(19) United States
(12) Patent Application Publication
(10) Pub. No.: US 2023/0223368 A1
(43) Pub. Date: Jul. 13, 2023

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventor: Zengyan FAN, Hefei City (CN)

(21) Appl. No.: 17/661,363

(22) Filed: Apr. 29, 2022

Related U.S. Application Data
(63) Continuation of application No. PCT/CN2022/078747, filed on Mar. 2, 2022.

(30) Foreign Application Priority Data
Jan. 13, 2022 (CN) 202210037101.0

(51) Int. Cl. H01L 23/00

(52) U.S. Cl. CPC H01L 24/14; H01L 24/11; H01L 2224/10126; H01L 2224/11013; H01L 2224/14517

(57) ABSTRACT

Embodiments of the present disclosure relate to a semiconductor structure and a manufacturing method thereof. The method includes: providing a base, wherein a pad is provided on the base; forming an insulating layer on the base, wherein the insulating layer is provided with an opening that exposes the pad; forming a first metal bump in the opening, wherein the first metal bump is in contact with the pad; forming a second metal bump on an upper surface of the insulating layer; forming an insulation structure at least on the upper surface of the insulating layer, wherein the insulation structure is in contact with a sidewall of the second metal bump. An adhesion between the insulation structure and the insulating layer is greater than an adhesion between the second metal bump and the insulating layer.

### CROSS-REFERENCE TO RELATED APPLICATIONS

This is a continuation of International Application No. PCT/CN2022/078747, filed on Mar. 2, 2022, which claims the priority to Chinese Patent Application 202210037101.0, titled “SEMICONDUCTOR STRUCTURE AND MANUFACTURING METHOD THEREOF” and filed with China National Intellectual Property Administration (CNIPA) on Jan. 13, 2022. The entire contents of International Application No. PCT/CN2022/078747 and Chinese Patent Application 202210037101.0 are incorporated herein by reference.

### TECHNICAL FIELD

Embodiments of the present disclosure relate to the technical field of semiconductors, in particular to a semiconductor structure and a manufacturing method thereof.

### BACKGROUND

In typical flip packaging of a chip, metal pads on a wafer need to be provided with metal bumps, so as to be electrically connected to a substrate of the package. To achieve good contact between the wafer and the substrate, dummy bumps will be formed on an insulating layer before the flip packaging. The dummy bumps easily fall off during the flip packaging process, which affects the contact between the wafer and the substrate, resulting in pseudo soldering, poor soldering, and the like, thus affecting the reliability of a packaged device. How to prevent the dummy bumps from falling off during the packaging process has become an urgent problem.

### SUMMARY

Embodiments of the present disclosure provide a semiconductor structure and a manufacturing method thereof.

The present disclosure provides a semiconductor structure, including:

a base comprising a pad;

an insulating layer, located on the base and provided with an opening that exposes the pad;

a first metal bump, located in the opening and being in contact with the pad;

a second metal bump, located on an upper surface of the insulating layer; and

an insulation structure, located on the upper surface of the insulating layer and being in contact with a sidewall of the second metal bump;

wherein an adhesion between the insulation structure and the insulating layer is greater than an adhesion between the second metal bump and the insulating layer.

The present disclosure further provides a method of manufacturing a semiconductor structure, including:

providing a base comprising a pad;

forming an insulating layer on the base, wherein the insulating layer is provided with an opening that exposes the pad;

forming a first metal bump in the opening, wherein the first metal bump is in contact with the pad;

forming a second metal bump on an upper surface of the insulating layer; and

forming an insulation structure on at least the upper surface of the insulating layer, wherein the insulation structure is in contact with a sidewall of the second metal bump;

wherein an adhesion between the insulation structure and the insulating layer is greater than an adhesion between the second metal bump and the insulating layer.

### BRIEF DESCRIPTION OF THE DRAWINGS

To describe the technical solutions in the embodiments of the present disclosure or in the related art more clearly, the following briefly describes the accompanying drawings required for describing the embodiments or the related art. Apparently, the accompanying drawings in the following description show merely some embodiments of the present disclosure, and a person of ordinary skill in the art may still derive other drawings from these accompanying drawings without creative efforts.

FIG. 1 is a schematic flowchart of a method of manufacturing a semiconductor structure according to an embodiment;

FIG. 2 is a schematic cross-sectional diagram of a semiconductor structure after an opening is formed according to an embodiment;

FIG. 3 is a schematic cross-sectional diagram of a semiconductor structure after a second metal bump is formed according to an embodiment corresponding to FIG. 2;

FIG. 4 is a schematic cross-sectional diagram of a semiconductor structure after an insulation structure is formed according to a first embodiment corresponding to FIG. 3;

FIG. 5 is a schematic cross-sectional diagram of a semiconductor structure after an insulation structure is formed according to a second embodiment corresponding to FIG. 3;

FIG. 6 is a schematic cross-sectional diagram of a semiconductor structure after an insulation structure is formed according to a third embodiment corresponding to FIG. 3;

FIG. 7 is a schematic cross-sectional diagram of a semiconductor structure after an insulation structure is formed according to a fourth embodiment corresponding to FIG. 3;

FIG. 8 is a top view of a semiconductor structure according to an embodiment corresponding to FIG. 7;

FIG. 9 is a schematic cross-sectional diagram of a semiconductor structure after an insulation structure is formed according to a fifth embodiment corresponding to FIG. 3;

FIG. 10 is a top view of a semiconductor structure according to an embodiment corresponding to FIG. 9;

FIG. 11 is a schematic cross-sectional diagram of a semiconductor structure after an insulation structure is formed according to a sixth embodiment corresponding to FIG. 3;

FIG. 12 is a top view of a semiconductor structure according to an embodiment corresponding to FIG. 11;

FIG. 13 is a schematic cross-sectional diagram of a semiconductor structure after an insulation structure is formed according to a seventh embodiment corresponding to FIG. 3; and

FIG. 14 is a top view of a semiconductor structure according to an embodiment corresponding to FIG. 13.

### DETAILED DESCRIPTION

To facilitate the understanding of embodiments of the present disclosure, the embodiments of the present disclosure are described more completely below with reference to the accompanying drawings. The preferred embodiments of the present disclosure are shown in the accompanying drawings. However, the embodiments of the present disclosure may be embodied in various forms without being limited to the embodiments described herein. On the contrary, these embodiments are provided to make the embodiments of the present disclosure more thorough and comprehensive.

Unless otherwise defined, all technical and scientific terms used herein have the same meaning as commonly understood by those skilled in the technical field of the embodiments of the present disclosure. The terms used in specifications of the embodiments of the present disclosure are merely for the purpose of describing specific embodiments, rather than to limit the embodiments of the present disclosure. The term “and/or” used herein includes any and all combinations of one or more of the associated is listed items. It should be understood that in the description of the embodiments of the present disclosure, the terms such as “upper”, “lower”, “vertical”, “horizontal”, “inner” and “outer” indicate the orientation or position relationships based on the drawings. These terms are merely intended to facilitate description of the embodiments of the present disclosure and simplify the description, rather than to indicate or imply that the mentioned device or element must have a specific orientation and must be constructed and operated in a specific orientation. Therefore, these terms should not be construed as a limitation to the embodiments of the present disclosure.

It is understandable that the terms such as “first” and “second” used herein may be used to describe various elements, but these elements are not limited by these terms. Instead, these terms are merely intended to distinguish one element from another. For example, without departing from the scope of the present disclosure, the first metal bump may be referred to as the second metal bump, and similarly, the second bump may be referred to as the first metal bump. Both the first metal bump and the second metal bump are metal bumps, but are not the same one. In addition, the terms such as “first” and “second” are only used for descriptive purposes, and should not be construed as indicating or implying relative importance or implying the number of indicated technical features. Thus, features limited by “first” and “second” may expressly or implicitly include at least one of that feature. In the description of the present disclosure, “a plurality of” means at least two, such as two or three, unless otherwise expressly and specifically defined. In the description of the present disclosure, “several” means at least one, such as one or two, unless otherwise expressly and specifically defined.

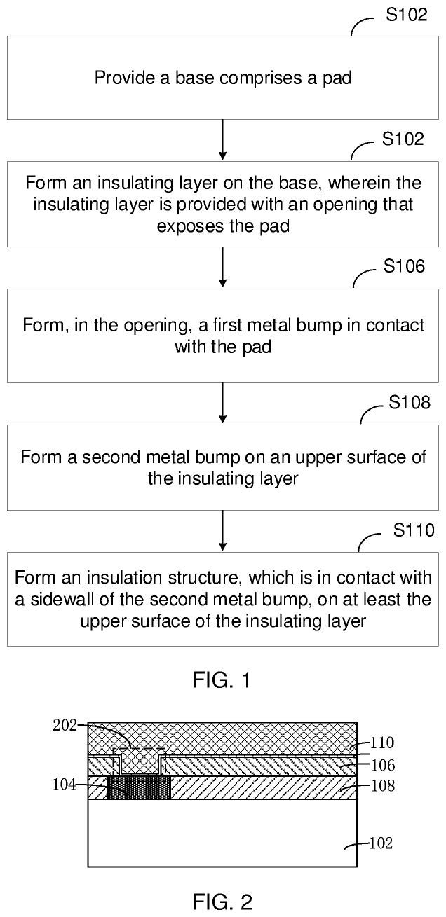

FIG. 1 is a schematic flowchart of a method of manufacturing a semiconductor structure according to an embodiment. As shown in FIG. 1, in the present embodiment, a method of manufacturing a semiconductor structure is provided, including the following steps.

S102: Provide a base comprising a pad.

Specifically, a base is provided, wherein a pad is provided on the base. The base may be made of undoped monocrystalline silicon, doped monocrystalline silicon, silicon-on-insulator (SOI), stacked silicon-on-insulator (SSOI), stacked silicon-germanium-on-insulator (S-SiGeOI), silicon-germanium-on-insulator (SiGeOI), and germanium-on-insulator (GeOI), etc. As an example, in the present embodiment, monocrystalline silicon is selected as a constituent material of the base. A device layer is formed in the base. The pad is used to lead out an external endpoint of the device layer and subsequently transmit signals to the device layer through the pad. For example, a constituent material of the pad includes one or more selected from a group consisting of polysilicon, a metal, a conductive metal nitride, a conductive metal oxide, and a metal silicide. The metal may be tungsten (W), nickel (Ni), aluminum (Al) or titanium (Ti); the conductive metal nitride includes titanium nitride (TiN); the conductive metal oxide includes iridium oxide (IrO₂); the metal silicide includes titanium silicide (TiSi). When polysilicon is selected as the constituent material of the pad, polysilicon is doped to be electrically conductive.

S104: Form an insulating layer on the base, wherein the insulating layer is provided with an opening that exposes the pad.

Specifically, an insulating layer is formed on the base, wherein the insulating layer is provided with an opening that exposes the pad. The insulating layer insulates the device layer in the base, to protect the device layer from the external environment. For example, a constituent material of the insulating layer may include one or more selected from a group consisting of an oxide, a nitride, and an imide polymer. The oxide may be silicon dioxide, the nitride may be silicon nitride, and the imide polymer may be polyimide (PI).

S106: Form, in the opening, a first metal bump that is in contact with the pad.

Specifically, a first metal bump is formed in the opening, the first metal bump is in electrical contact with the pad, and the first metal bump may lead out the pad to a surface of the insulating layer. For example, a constituent material of the first metal bump includes one or more selected from a group consisting of a metal, a conductive metal nitride, a conductive metal oxide, and a metal silicide. The metal may be tungsten (W), nickel (Ni), aluminum (Al), copper (Cu), tin (Sn) or titanium (Ti); the conductive metal nitrides titanium nitride (TiN); the conductive metal oxide includes iridium oxide (IrO₂); the metal silicide includes titanium silicide (TiSi).

S108: Form a second metal bump on an upper surface of the insulating layer.

Specifically, a second metal bump is formed on the upper surface of the insulating is layer. It may be understood that a lower surface of the second metal bump is in contact with the upper surface of the insulating layer. The second metal bump cannot transmit signals, and is mainly used as a dummy bump, so that good contact is formed between the base and a substrate that is used in a flip packaging process. A metal connection line is formed in the substrate, and the external endpoint of the device layer is led out to a predetermined position on the substrate through the first metal bump and the metal connection line in the substrate. For example, a constituent material of the second metal bump is the same as a constituent material of the first metal bump. The first metal bump and the second metal bump can be formed simultaneously, or the first metal bump and the second metal bump may be formed in different steps. It may be understood that the second metal bump does not transmit signals. In practice, the second metal bump may be replaced with an insulation bump or a semiconductor bump made of a semiconductor material, as long as it can reduce the size of an overhanging space between the substrate and the base.

S110: Form an insulation structure, which is in contact with a sidewall of the second metal bump, on at least the upper surface of the insulating layer.

Specifically, an insulation structure is formed at least on the upper surface of the insulating layer, wherein the insulation structure is in contact with a sidewall of the second metal bump. An adhesion between the insulation structure and the insulating layer is greater than an adhesion between the second metal bump and the insulating layer, so that the insulation structure can support and secure the second metal bump, and reduce the fall-off risk of the second metal bump. Moreover, the insulation structure can block the second metal bump if the second metal bump falls off, thus reducing the fall-off speed and risk of the second metal bump.

For example, a constituent material of the insulation structure includes one or more selected from a group consisting of an oxide, a nitride, and an imide polymer. The oxide may be silicon dioxide, the nitride may be silicon nitride, and the imide polymer may be polyimide (PI).

In an embodiment, a material of the insulation structure is different from a material of the insulating layer. In another embodiment, the material of the insulation structure is the is same as the material of the insulating layer. By configuring a greater adhesion between the insulation structure and the insulating layer, the fall-off risk of the second metal bump can be better reduced.

The foregoing method of manufacturing a semiconductor structure includes providing a base having a pad; forming an insulating layer on the base, wherein the insulating layer is provided with an opening that exposes the pad; forming a first metal bump in the opening, wherein the first metal bump is in contact with the pad; forming a second metal bump on an upper surface of the insulating layer; forming an insulation structure at least on the upper surface of the insulating layer, wherein the insulation structure is in contact with a sidewall of the second metal bump, wherein an adhesion between the insulation structure and the insulating layer is greater than an adhesion between the second metal bump and the insulating layer. By forming, on the upper surface of the insulating layer, the insulation structure in contact with the sidewall of the second metal bump, the fall-off risk the second metal bump is reduced. Moreover, because the adhesion between the insulation structure and the insulating layer is greater than the adhesion between the second metal bump and the insulating layer, the insulation structure secures the second metal bump, which further reduces the fall-off risk of the second metal bump, reduces the probability of pseudo soldering and poor soldering, and improves the reliability of the semiconductor structure.

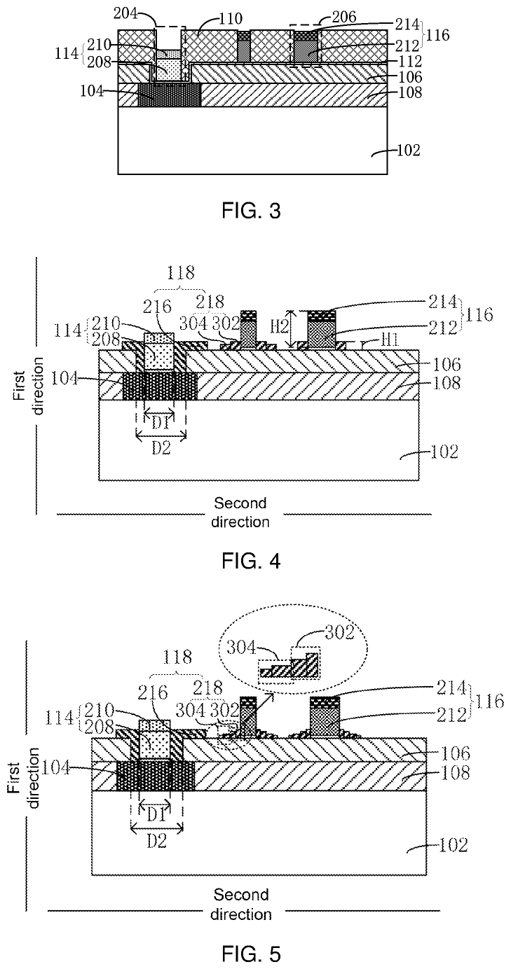

FIG. 2 is a schematic cross-sectional diagram of a semiconductor structure after an opening is formed according to an embodiment; FIG. 3 is a schematic cross-sectional diagram of a semiconductor structure after a second metal bump is formed according to an embodiment corresponding to FIG. 2. As shown in FIG. 2 and FIG. 3, in the first step, a base 102 is provided, wherein a pad 104 is provided on the base 102; an insulating layer 106 is formed on the base 102, wherein the insulating layer 106 is provided with an opening 202 that exposes the pad 104. It may be understood that, the method of manufacturing a semiconductor structure further includes: filling a spacer layer 108 between adjacent pads 104, wherein an upper surface of the spacer layer 108 is flush with an upper surface of each pad 104. For example, a constituent material of the spacer layer 108 includes one or more selected from a group consisting of an oxide, a nitride, is and an imide polymer. The oxide may be silicon dioxide, the nitride may be silicon nitride, and the imide polymer may be polyimide (PI). In the second step, a photoresist layer 110 is formed on the base 102, wherein the opening 202 is filled with the photoresist layer, and the photoresist layer 110 is patterned through exposure and development, to form, in the photoresist layer 110, a first trench 204 constituting a pattern of the first metal bump 114 and a second trench 206 constituting a pattern of the second metal bump 116. For example, to make it easy to form the first metal bump 114 and the second metal bump 116 subsequently, before the photoresist layer 110 is formed on the base 102, the method further includes: forming a seed layer 112 on the base 102, wherein the seed layer 112 covers an inner wall of the opening 202, and extends along a sidewall of the opening 202 to cover the upper surface of the insulating layer 106. In the third step, the first trench 204 is filled to form the first metal bump 114, and the second trench 206 is filled to form the second metal bump 116. For example, the first metal bump 114 and the second metal bump 116 are formed through electroplating. For example, the first metal bump 114 includes a first metal layer 208 and a second metal layer 210 located on an upper surface of the first metal layer 208; the second metal bump 116 includes a third metal layer 212 and a fourth metal layer 214 located on an upper surface of the third metal layer 212. For example, a constituent material of the first metal layer 208 is the same as a constituent material of the third metal layer 212, and a constituent material of the second metal layer 210 is the same as a constituent material of the fourth metal layer 214. For example, the first metal layer 208 and the third metal layer 212 are formed simultaneously; the second metal layer 210 and the fourth metal layer 214 are formed simultaneously. That is, the first metal bump 114 and the second metal bump 116 are formed simultaneously. For example, a constituent material of the seed layer 112 is the same as a constituent material of the first metal layer 208 and the third metal layer 212. The constituent materials of the first metal layer 208, second metal layer 210, third metal layer 212, and the fourth metal layer 214 include one or more selected from a group consisting of tungsten (W), nickel (Ni), aluminum (Al), copper (Cu), tin (Sn) or titanium (Ti). In the fourth step, the photoresist layer 110 and the seed layer 112 under the photoresist layer 110 are removed, and only the seed layer 112 under the first metal bump 114 and the second metal bump 116 is is retained.

FIG. 4 is a schematic cross-sectional diagram of a semiconductor structure after an insulation structure is formed according to a first embodiment corresponding to FIG. 3. As shown in FIG. 4, in the fourth step, an insulation structure 118 in contact with a sidewall of the second metal bump 116 is formed on at least an upper surface of the insulating layer 106. Specifically, an insulation material layer is first formed on the upper surface of the insulating layer 106; next, a patterned mask layer is formed on the insulation material layer, wherein the patterned mask layer defines a shape and a position of the insulation structure 118; then, a redundant part of the insulation material layer is removed through photoetching by using the patterned mask layer as a mask, so as to obtain the insulation structure 118.

In an embodiment, at least two of the insulating layer 106, the spacer layer 108, and the insulation structure 118 are made of a same material. In other embodiments, constituent materials of the insulating layer 106, the spacer layer 108, and the insulation structure 118 are different from each other.

Further referring to FIG. 4, in an embodiment, the insulation structure 118 includes a first insulation structure 216 and a second insulation structure 218. The first insulation structure 216 is in contact with a sidewall of the first metal bump 114, and the second insulation structure 218 is in contact with a sidewall of the second metal bump 116. This configuration can stabilize the first metal bump 114.

Further referring to FIG. 4, in an embodiment, two or more second metal bumps 116 are provided, and the second insulation structure 218 on the sidewall of at least one of the second metal bumps 116 is in a shape different from shapes of the second insulation structures 218 on the sidewalls of other second metal bumps 116. In other embodiments, the second insulation structures 218 on the sidewalls of the second metal bumps 116 are in the same shape (not shown in the figure).

Further referring to FIG. 4, in an embodiment, the second insulation structure 218 includes a first part 302 and a second part 304. The first part 302 is in contact with the sidewall of the second metal bump 116; the second part 304 is in contact with a sidewall of the first part 302 that is away from the second metal bump 116.

Further referring to FIG. 4, in an embodiment, a thickness of the first part 302 is greater than a thickness of the second part 304. For example, as shown in FIG. 4, cross sections of the first part 302 and the second part 304 are rectangular; a thickness of the first part 302 in a first direction is greater than a thickness of the second part 304 in the first direction. The first direction is a direction pointing to the insulating layer 106 from the base 102, and the second direction is a direction of a line connecting the first metal bump 114 and the second metal bump 116. In addition, the second direction is perpendicular to the first direction. Such a configuration makes it easy to fill a filler material in a space on the second insulation structure 218 during flip packaging.

FIG. 5 is a schematic cross-sectional diagram of a semiconductor structure after an insulation structure is formed according to a second embodiment corresponding to FIG. 3. As shown in FIG. 5, in an embodiment, the first part 302 and the second part 304 are each in a stepped shape. For example, the first part 302 and the second part 304 are each consist of a plurality of rectangular structures with rectangular cross sections (in FIG. 5, the first part 302 and the second part 304 each including 2 rectangular structures is taken as an example for description). In the first part 302, thicknesses of the rectangular structures in the first direction gradually decrease as the distance from the sidewall of the second metal bump 116 increases; in the second part 304, thicknesses of the rectangular structures in the first direction gradually decrease as the distance from the sidewall of the second metal bump 116 increases. Such a configuration makes it easy to fill a filler material in a space on the second insulation structure 218 during flip packaging.

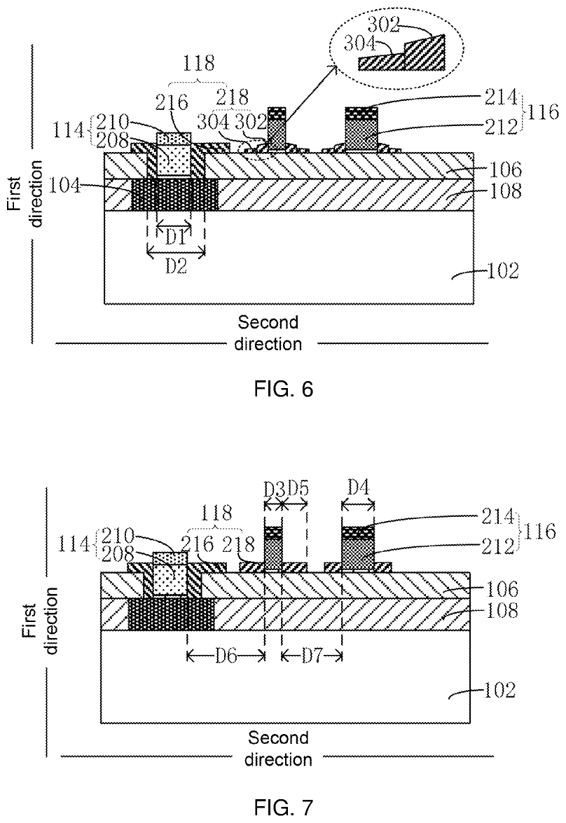

FIG. 6 is a schematic cross-sectional diagram of a semiconductor structure after an insulation structure is formed according to a third embodiment corresponding to FIG. 3. As shown in FIG. 6, in an embodiment, the thickness of the first part 302 in the first direction decreases as the distance between the first part 302 and the second metal bump 116 increases in the second direction; the thickness of the second part 304 in the first direction decreases as the distance between the second part 304 and the second metal bump 116 increases in the second direction. It may be understood that, a variation trend of the thickness of the first part 302 in the first direction over the distance between the first part 302 and the second metal bump 116 in the second direction may be the same is as or different from a variation trend of the thickness of the second part 304 in the first direction over the distance between the second part 304 and the second metal bump 116 in the second direction.

Further referring to FIG. 6, in an embodiment, the thickness of the first part 302 is greater than the thickness of the second part 304. That is, a minimum thickness of the first part 302 in the first direction is greater than a maximum thickness of the second part 304 in the first direction. The thickness of the second insulation structure 218 in the first direction decreases as the distance between the second insulation structure 218 and the second metal bump 116 increases in the second direction. Such a configuration makes it easier to fill a filler material between the second metal bump 116 and the second metal bump 116 and/or between the first metal bump 114 and the second metal bump 116 during flip packaging.

In other embodiments, the minimum thickness of the first part 302 in the first direction is less than or equal to the maximum thickness of the second part 304 in the first direction (not shown in the figure).

Further referring to FIG. 4, in an embodiment, a width D1 of the first metal bump 114 is less than a width D2 of the opening 202, and the first insulation structure 216 is further formed between sidewalls of the first metal bump 114 and the opening 202. The first insulation structure 216 can reduce the tipping or fall-off risk of the first metal bump 114.

Further referring to FIG. 4, in an embodiment, a thickness of the first metal bump 114 is greater than a thickness of the second metal bump 116. Specifically, a thickness of the first metal bump 114 in the first direction is greater than a thickness of the second metal bump 116 in the first direction.

Further referring to FIG. 4, for example, the width of the second insulation structure 218 in the second direction is greater than or equal to 3 um. For example, the width of the second insulation structure 218 in the second direction includes 3 um, 3.2 um, 3.5 um, 3.7 um, 3.9 um, 4.0 um, 4.2 um, 4.4 um, 4.6 um, 4.9 um, or 5.0 um. The thickness of the second insulation structure 218 in the first direction is greater than or equal to 5 um. For example, the thickness of the second insulation structure 218 in the first direction includes 5.0 um, 5.2 um, 5.5 um, 5.7 um, 5.9 um, or 6.0 um. A ratio of a maximum thickness H1 of is the second insulation structure 218 in the first direction to a thickness H2 of the second metal bump 116 on the sidewall of the second insulation structure 218 in the first direction is 1:4 to 1:6.

In an embodiment, the thickness of the second insulation structure 218 is inversely proportional to a dimension of the second metal bump 116. Specifically, as a length of the second metal bump 116 in the second direction decreases, the second insulation structure 218 in contact with the sidewall of the second metal bump 116 has a larger thickness in the first direction. Such a configuration can increase a contact area between the second metal bump 116 and the second insulation structure 218, thereby reducing the fall-off risk of the second metal bump.

In an embodiment, a dimension of the second insulation structure 218 is inversely proportional to the dimension of the second metal bump 116. Specifically, as the length of the second metal bump 116 in the second direction decreases, the second insulation structure 218 in contact with the sidewall of the second metal bump 116 has a larger length in the second direction. Such a configuration enables the second insulation structure 218 to secure the second metal bump 116 more firmly, thereby reducing the fall-off risk of the second metal bump.

Further referring to FIG. 4, in an embodiment, the sidewall of the first metal bump 114 includes: a first sidewall located between an upper surface of the pad 104 and the upper surface of the insulating layer 106, and a second sidewall higher than the upper surface of the insulating layer 106. The first insulation structure 216 is at least in contact with a part of the second sidewall. The first insulation structure 216 can reduce the tipping or fall-off risk of the first metal bump 114.

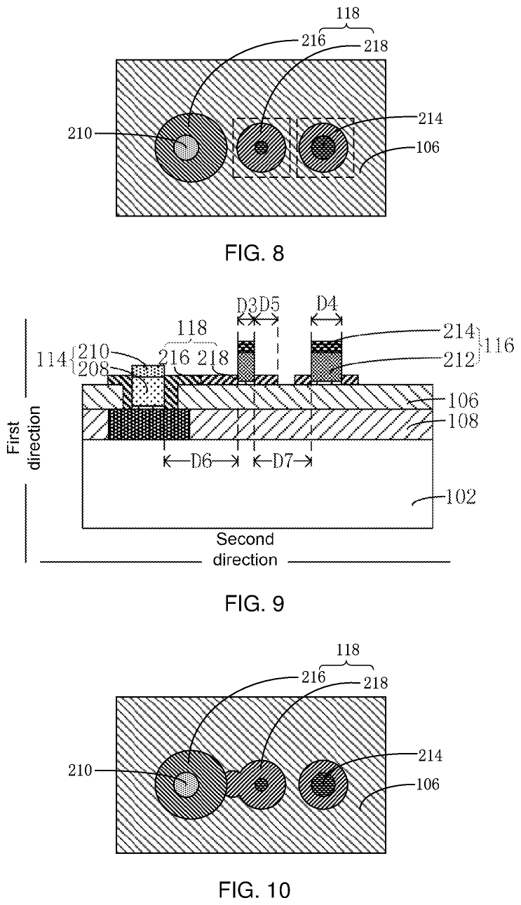

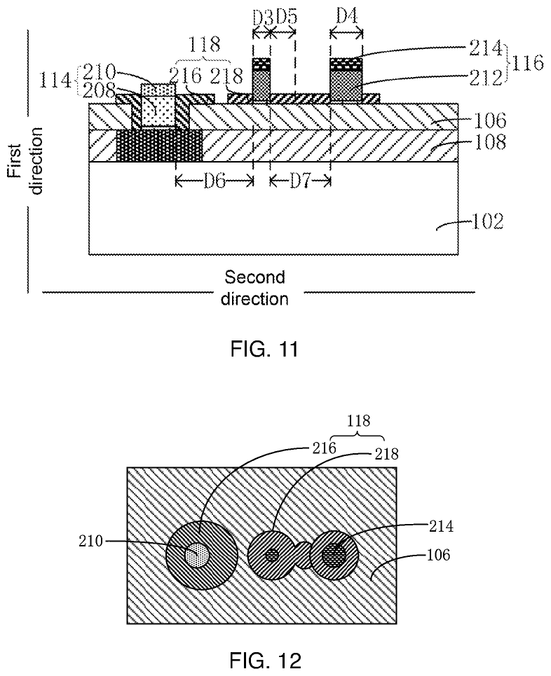

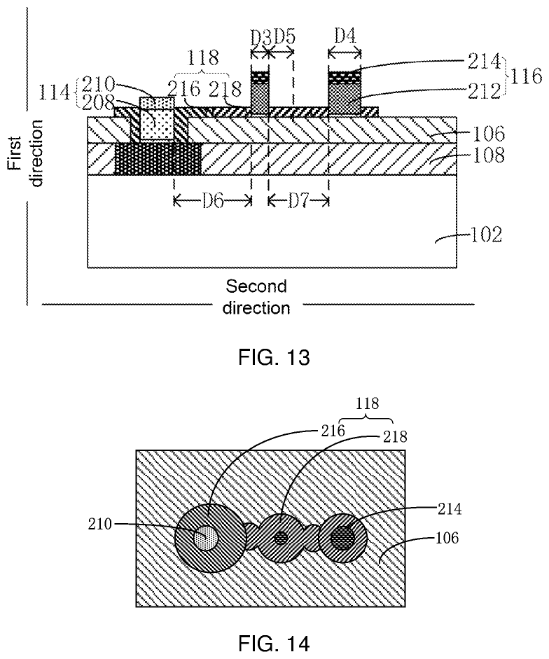

FIG. 7 is a schematic cross-sectional diagram of a semiconductor structure after an insulation structure is formed according to a fourth embodiment corresponding to FIG. 3; FIG. 8 is a top view of a semiconductor structure according to an embodiment corresponding to FIG. 7; FIG. 9 is a schematic cross-sectional diagram of a semiconductor structure after an insulation structure is formed according to a fifth embodiment corresponding to FIG. 3; FIG. 10 is a top view of a semiconductor structure according to an embodiment corresponding to FIG. 9; FIG. 11 is a schematic cross-sectional diagram of a semiconductor structure after an insulation structure is formed according to a sixth embodiment corresponding to FIG. 3; FIG. 12 is a top view of a semiconductor structure according to an embodiment corresponding to FIG. 11; FIG. 13 is a schematic cross-sectional diagram of a semiconductor structure after an insulation structure is formed according to a seventh embodiment corresponding to FIG. 3; and FIG. 14 is a top view of a semiconductor structure according to an embodiment corresponding to FIG. 13. As shown in FIG. 7 and FIG. 8, in an embodiment, when a difference ΔD (D3<D4) between dimensions D3 and D4 of two adjacent second metal bumps 116 meets a first preset condition, a dimension D5 of the second insulation structure 218 on the sidewall of the second metal bump 116 with the dimension D3 is increased, to eliminate a stress difference between the second metal bump 116 with the dimension D3 and the second metal bump 116 with the dimension D4 caused by the dimension difference. The first preset condition refers to that the difference ΔD is greater than or equal to a preset value. For example, the preset value causes an area difference between two adjacent second metal bumps 116 to be greater than or equal to 4 times the area of the second metal bump 116 with the dimension D3. For example, when the dimensions D3 and D4 of the second metal bumps 116 are both less than 100 um and greater than 40 um, the first preset condition refers to that the difference ΔD is 15 um to 20 um, e.g., the difference ΔD is 15 um, 17 um, 19 um, 20 um or the like. When the dimensions D3 and D4 of the second metal bumps 116 are both less than or equal to 40 um, the first preset condition refers to that the difference ΔD is 5 um to 15 um, e.g., the difference ΔD is 5 um, 7 um, 9 um, 10 um, 13 um or the like. For example, when the second insulation structure 218 surrounds the second metal bump 116, the dimension D5 of the second insulation structure 218 on the sidewall of the second metal bump 116 with the dimension D3 is increased to increase the area of the second insulation structure 218 surrounding the second metal bump 116 with the dimension D3, thereby eliminating the stress difference caused by the area difference of two adjacent second metal bumps 116. For example, a total area S1 of the second metal bump 116 with the dimension D3 and the second insulation structure 218 on the sidewall thereof is equal to a total area S2 of the second metal bump 116 with the dimension D4 and the second insulation structure 218 on the sidewall thereof. That is, two parts framed with dashed boxes in FIG. 8 have the same area.

As shown in FIG. 7, in an embodiment, when the dimension D3 of the second metal bump 116 is greater than or equal to a preset dimension, the second insulation structure 218 on the sidewall of the second metal bump 116 is spaced apart from the first insulation structure 216 on the sidewall of the neighboring first metal bump 114, and the second insulation structure 218 on the sidewall of the second metal bump 116 is spaced apart from the second insulation structure 218 on the sidewall of the neighboring second metal bump 116. When a distance D6 between the second metal bump 116 and the neighboring first metal bump 114 meets a second preset condition, and a distance D7 between the second metal bump 116 and the neighboring second metal bump 116 meets a third preset condition, the second insulation structure 218 on the sidewall of the second metal bump 116 is spaced apart from the first insulation structure 216 on the sidewall of the neighboring first metal bump 114, and the second insulation structure 218 on the sidewall of the second metal bump 116 is spaced apart from the second insulation structure 218 on the sidewall of the neighboring second metal bump 116. The preset dimension refers to a dimension of the second metal bump 116 in a case that the second metal bump 116 can be prevented from falling off or tipping by adding the second insulation structure 218 to the sidewall of the second metal bump 116. The second preset condition refers to that a difference between the distance D6 and the dimension of the second insulation structure 218 added to the sidewall of the second metal bump 116 is greater than the dimension of the first insulation structure 216 added to the sidewall of the neighboring first metal bump 114. The third preset condition refers to that a difference between the distance D7 and the dimension of the second insulation structure 218 added to the sidewall of the second metal bump 116 is greater than the dimension of the second insulation structure 218 added to the sidewall of the second metal bump 116. For example, the distance D6 is equal to the distance D7, and the distance D7 is greater than or equal to 20 um and less than or equal to 105 um, e.g., D7 is 30 um, 40 um, 45 um, 50 um, 70 um, 90 um, 100 um, etc.

In an embodiment, the insulation structure surrounds the second metal bump. As is shown in FIG. 8, the second insulation structure 218 surrounds the second metal bump 116, which can further prevent the second metal bump 116 from falling off or tipping. The first insulation structure 216 surrounds the first metal bump 114, which can further prevent the first metal bump 114 from falling off or tipping.

As shown in FIG. 9 and FIG. 10, in an embodiment, when the dimension D3 of the second metal bump 116 is less than the preset dimension, the distance D6 between the second metal bump 116 and the neighboring first metal bump 114 does not meet the second preset condition, and the distance D7 between the second metal bump 116 and the neighboring second metal bump 116 meets the third preset condition, the second insulation structure 218 on the sidewall of the second metal bump 116 is in contact with the first insulation structure 216 on the sidewall of the neighboring first metal bump 114, and the second insulation structure 218 on the sidewall of the second metal bump 116 is spaced apart from the second insulation structure 218 on the sidewall of the neighboring second metal bump 116. Such a configuration can prevent the first metal bump 114 and the second metal bump 116 from falling off or tipping.

As shown in FIG. 11 and FIG. 12, in an embodiment, when the dimension D3 of the second metal bump 116 is less than the preset dimension, the distance D6 between the second metal bump 116 and the neighboring first metal bump 114 meets the second preset condition, and the distance D7 between the second metal bump 116 and the neighboring second metal bump 116 does not meet the third preset condition, the second insulation structure 218 on the sidewall of the second metal bump 116 is spaced apart from the first insulation structure 216 on the sidewall of the first metal bump 114, and the second insulation structure 218 on the sidewall of the second metal bump 116 is in contact with the second insulation structure 218 on the sidewall of the second metal bump 116. Such a configuration can prevent the second metal bump 116 from falling off or tipping.

As shown in FIG. 13 and FIG. 14, in an embodiment, when the dimension D3 of the second metal bump 116 is less than the preset dimension, the distance D6 between the second metal bump 116 and the neighboring first metal bump 114 does not meet the second preset condition, and the distance D7 between the second metal bump 116 and the neighboring second metal bump 116 does not meet the third preset condition, the second insulation structure 218 on the sidewall of the second metal bump 116 is in contact with the first insulation structure 216 on the sidewall of the first metal bump 114, and the second insulation structure 218 on the sidewall of the second metal bump 116 is in contact with the second insulation structure 218 on the sidewall of the second metal bump 116. Such a configuration can prevent the first metal bump 114 and the second metal bump 116 from falling off or tipping.

It should be understood that although the steps in the flowchart of FIG. 1 are sequentially displayed according to the arrows, these steps are not necessarily executed in the order indicated by the arrows. Unless clearly described otherwise, the execution order of the steps is not strictly limited, and these steps may be executed in other orders. Moreover, at least some of the steps in FIG. 1 may include a plurality of sub-steps or stages. The sub-steps or stages are not necessarily executed at the same time, but may be executed at different times. The execution order of the sub-steps or stages is not necessarily carried out sequentially, but may be executed alternately with other steps or at least some of the sub-steps or stages of other steps.

As shown in FIG. 2 and FIG. 4, the present disclosure provides a semiconductor structure, including: a base 102, an insulating layer 106, a first metal bump 114, a second metal bump 116, and an insulation structure 118. A pad 104 is provided on the base 102; the insulating layer 106 is located on the base 102, and is provided with an opening 202 that exposes the pad 104; the first metal bump 114 is located in the opening 202 and in contact with the pad 104; the second metal bump 116 is located on an upper surface of the insulating layer 106; the insulation structure 118 is located on the upper surface of the insulating layer 106, and is in contact with a sidewall of the second metal bump 116. An adhesion between the insulation structure 118 and the insulating layer 106 is greater than an adhesion between the second metal bump 116 and the insulating layer 106.

Specifically, the base 102 may be made of undoped monocrystalline silicon, doped monocrystalline silicon, silicon-on-insulator (SOI), stacked silicon-on-insulator (SSOI), stacked silicon-germanium-on-insulator (S-SiGeOI), silicon-germanium-on-insulator (SiGeOI), and germanium-on-insulator (GeOI), etc. As an example, in the present embodiment, monocrystalline silicon is selected as the constituent material of the base 102. A device layer is formed in the base 102. The pad 104 is used to lead out an external endpoint of the device layer and subsequently transmit signals to the device layer through the pad 104. For example, a constituent material of the pad 104 includes one or more selected from a group consisting of polysilicon, a metal, a conductive metal nitride, a conductive metal oxide, and a metal silicide. The metal may be tungsten (W), nickel (Ni), aluminum (Al) or titanium (Ti); the conductive metal nitride includes titanium nitride (TiN); the conductive metal oxide includes iridium oxide (IrO₂); the metal silicide includes titanium silicide (TiSi). When polysilicon is selected as the constituent material of the pad 104, polysilicon is doped to be electrically conductive. Specifically, the insulating layer 106 is provided with the opening 202 that exposes the pad 104. The insulating layer 106 insulates the device layer in the base 102, to protect the device layer from the external environment. For example, a constituent material of the insulating layer 106 may include one or more selected from a group consisting of an oxide, a nitride, and an imide polymer. The oxide may be silicon dioxide, the nitride may be silicon nitride, and the imide polymer may be polyimide (PI). The first metal bump 114 is in electrical contact with the pad 104, and the first metal bump 114 may lead out the pad 104 to a surface of the insulating layer 106. For example, a constituent material of the first metal bump 114 includes one or more selected from a group consisting of a metal, a conductive metal nitride, a conductive metal oxide, and a metal silicide. The metal may be tungsten (W), nickel (Ni), aluminum (Al), copper (Cu), tin (Sn) or titanium (Ti); the conductive metal nitrides titanium nitride (TiN); the conductive metal oxide includes iridium oxide (IrO₂); the metal silicide includes titanium silicide (TiSi). It may be understood that a lower surface of the second metal bump 116 is in contact with the upper surface of the insulating layer. The second metal bump 116 cannot transmit signals, and is mainly used as a dummy bump, so that good contact is formed between the base 102 and a substrate that is used in a flip packaging process. A metal connection line is formed in the substrate, and the external endpoint of the device layer is led out to a predetermined position on the substrate through the first metal bump 114 and the metal connection line in the substrate. For example, a constituent material of the second metal bump 116 is the same as a constituent material of the first metal bump 114. It may be understood that the second metal bump 116 does not transmit signals. In practice, the second metal bump 116 may be replaced with an insulation bump or a semiconductor bump made of a semiconductor material, as long as it can reduce the size of an overhanging space between the substrate and the base 102. The insulation structure 118 is in contact with a sidewall of the second metal bump 116. An adhesion between the insulation structure 118 and the insulating layer 106 is greater than an adhesion between the second metal bump 116 and the insulating layer 106, so that the insulation structure 118 can support and secure the second metal bump 116, and reduce the fall-off risk of the second metal bump 116. Moreover, the insulation structure can block the second metal bump 116 if the second metal bump 116 falls off, thus reducing the fall-off speed and risk of the second metal bump 116.

For example, a constituent material of the insulation structure 118 includes one or more selected from a group consisting of an oxide, a nitride, and an imide polymer. The oxide may be silicon dioxide, the nitride may be silicon nitride, and the imide polymer may be polyimide (PI).

In an embodiment, a material of the insulation structure 118 is different from a material of the insulating layer 106. In another embodiment, the material of the insulation structure 118 is the same as the material of the insulating layer 106. By configuring a greater adhesion between the insulation structure 118 and the insulating layer 106, the fall-off risk of the second metal bump 116 can be better reduced.

The foregoing semiconductor structure includes a base having a pad; an insulating layer, located on the base and provided with an opening that exposes the pad; a first metal bump, located in the opening and being in contact with the pad; a second metal bump, located on an upper surface of the insulating layer; and an insulation structure, located on the upper surface of the insulating layer and being in contact with a sidewall of the second metal bump. An adhesion between the insulation structure and the insulating layer is greater than an adhesion between the second metal bump and the insulating layer. By forming, on the upper surface of the insulating layer, the insulation structure in contact with the sidewall of the second metal bump, the fall-off risk the second metal bump is reduced. Moreover, because the adhesion between the insulation structure and the insulating layer is greater than the adhesion between the second metal bump and is the insulating layer, the insulation structure secures the second metal bump, which further reduces the fall-off risk of the second metal bump, reduces the probability of pseudo soldering and poor soldering, and improves the reliability of the semiconductor structure.

As shown in FIG. 3, in an embodiment, the semiconductor structure further includes a spacer layer 108 filled between adjacent pads 104; an upper surface of the spacer layer 108 is flush with an upper surface of the pad 104. For example, a constituent material of the spacer layer 108 includes one or more selected from a group consisting of an oxide, a nitride, and an imide polymer. The oxide may be silicon dioxide, the nitride may be silicon nitride, and the imide polymer may be polyimide (PI).

Further referring to FIG. 3, in an embodiment, the semiconductor structure further includes a seed layer 112 that is located under the first metal bump 114 and under the second metal bump 116 and that is in contact with a lower surface of the first metal bump 114 and a lower surface of the second metal bump 116. The seed layer 112 helps form the first metal bump 114 and the second metal bump 116. For example, the first metal bump 114 includes a first metal layer 208 and a second metal layer 210 located on an upper surface of the first metal layer 208; the second metal bump 116 includes a third metal layer 212 and a fourth metal layer 214 located on an upper surface of the third metal layer 212. For example, a constituent material of the first metal layer 208 is the same as a constituent material of the third metal layer 212, and a constituent material of the second metal layer 210 is the same as a constituent material of the fourth metal layer 214. For example, a constituent material of the seed layer 112 is the same as a constituent material of the first metal layer 208 and the third metal layer 212. The constituent materials of the first metal layer 208, second metal layer 210, third metal layer 212, and the fourth metal layer 214 include one or more selected from a group consisting of tungsten (W), nickel (Ni), aluminum (Al), copper (Cu), tin (Sn) or titanium (Ti).

In an embodiment, at least two of the insulating layer 106, the spacer layer 108, and the insulation structure 118 are made of a same material. In other embodiments, constituent materials of the insulating layer 106, the spacer layer 108, and the insulation structure 118 are different from each other.

Further referring to FIG. 4, in an embodiment, the insulation structure 118 includes a is first insulation structure 216 and a second insulation structure 218. The first insulation structure 216 is in contact with a sidewall of the first metal bump 114, and the second insulation structure 218 is in contact with a sidewall of the second metal bump 116. This configuration can stabilize the first metal bump 114.

Further referring to FIG. 4, in an embodiment, two or more second metal bumps 116 are provided, and the second insulation structure 218 on the sidewall of at least one of the second metal bumps 116 is in a shape different from shapes of the second insulation structures 218 on the sidewalls of other second metal bumps 116. In other embodiments, the second insulation structures 218 on the sidewalls of the second metal bumps 116 are in the same shape (not shown in the figure).

Further referring to FIG. 4, in an embodiment, the second insulation structure 218 includes a first part 302 and a second part 304. The first part 302 is in contact with the sidewall of the second metal bump 116; the second part 304 is in contact with a sidewall of the first part 302 that is away from the second metal bump 116.

Further referring to FIG. 4, in an embodiment, a thickness of the first part 302 is greater than a thickness of the second part 304. For example, as shown in FIG. 4, cross sections of the first part 302 and the second part 304 are rectangular; a thickness of the first part 302 in a first direction is greater than a thickness of the second part 304 in the first direction. The first direction is a direction pointing to the insulating layer 106 from the base 102, and the second direction is a direction of a line connecting the first metal bump 114 and the second metal bump 116. In addition, the second direction is perpendicular to the first direction. Such a configuration makes it easy to fill a filler material in a space on the second insulation structure 218 during flip packaging.

As shown in FIG. 5, in an embodiment, the first part 302 and the second part 304 are each in a stepped shape. For example, the first part 302 and the second part 304 are each consist of a plurality of rectangular structures with rectangular cross sections (in FIG. 5, the first part 302 and the second part 304 each including 2 rectangular structures is taken as an example for description). In the first part 302, thicknesses of the rectangular structures in the first direction gradually decrease as the distance from the sidewall of the second metal bump 116 increases; in the second part 304, thicknesses of the rectangular structures in the first direction gradually decrease as the distance from the sidewall of the second metal bump 116 increases. Such a configuration makes it easy to fill a filler material in a space on the second insulation structure 218 during flip packaging. As shown in FIG. 6, in an embodiment, the thickness of the first part 302 in the first direction decreases as the distance between the first part 302 and the second metal bump 116 increases in the second direction; the thickness of the second part 304 in the first direction decreases as the distance between the second part 304 and the second metal bump 116 increases in the second direction. It may be understood that, a variation trend of the thickness of the first part 302 in the first direction over the distance between the first part 302 and the second metal bump 116 in the second direction may be the same as or different from a variation trend of the thickness of the second part 304 in the first direction over the distance between the second part 304 and the second metal bump 116 in the second direction.

Further referring to FIG. 6, in an embodiment, the thickness of the first part 302 is greater than the thickness of the second part 304. That is, a minimum thickness of the first part 302 in the first direction is greater than a maximum thickness of the second part 304 in the first direction. The thickness of the second insulation structure 218 in the first direction decreases as the distance between the second insulation structure 218 and the second metal bump 116 increases in the second direction. Such a configuration makes it easier to fill a filler material between the second metal bump 116 and the second metal bump 116 and/or between the first metal bump 114 and the second metal bump 116 during flip packaging.

In other embodiments, the minimum thickness of the first part 302 in the first direction is less than or equal to the maximum thickness of the second part 304 in the first direction (not shown in the figure).

Further referring to FIG. 4, in an embodiment, a width D1 of the first metal bump 114 is less than a width D2 of the opening 202, and the first insulation structure 216 is further formed between sidewalls of the first metal bump 114 and the opening 202. The first insulation structure 216 can reduce the tipping or fall-off risk of the first metal bump 114.

Further referring to FIG. 4, in an embodiment, a thickness of the first metal bump 114 is greater than a thickness of the second metal bump 116. Specifically, a thickness of the first metal bump 114 in the first direction is greater than a thickness of the second metal bump 116 in the first direction.

Further referring to FIG. 4, for example, the width of the second insulation structure 218 in the second direction is greater than or equal to 3 um. For example, the width of the second insulation structure 218 in the second direction includes 3 um, 3.2 um, 3.5 um, 3.7 um, 3.9 um, 4.0 um, 4.2 um, 4.4 um, 4.6 um, 4.9 um, or 5.0 um. The thickness of the second insulation structure 218 in the first direction is greater than or equal to 5 um. For example, the thickness of the second insulation structure 218 in the first direction includes 5.0 um, 5.2 um, 5.5 um, 5.7 um, 5.9 um, or 6.0 um. A ratio of a maximum thickness H1 of the second insulation structure 218 in the first direction to a thickness H2 of the second metal bump 116 on the sidewall of the second insulation structure 218 in the first direction is 1:4 to 1:6.

In an embodiment, the thickness of the second insulation structure 218 is inversely proportional to a dimension of the second metal bump 116. Specifically, as a length of the second metal bump 116 in the second direction decreases, the second insulation structure 218 in contact with the sidewall of the second metal bump 116 has a larger thickness in the first direction. Such a configuration can increase a contact area between the second metal bump 116 and the second insulation structure 218, thereby reducing the fall-off risk of the second metal bump.

In an embodiment, a dimension of the second insulation structure 218 is inversely proportional to the dimension of the second metal bump 116. Specifically, as the length of the second metal bump 116 in the second direction decreases, the second insulation structure 218 in contact with the sidewall of the second metal bump 116 has a larger length in the second direction. Such a configuration enables the second insulation structure 218 to secure the second metal bump 116 more firmly, thereby reducing the fall-off risk of the second metal bump.

In an embodiment, the sidewall of the first metal bump 114 includes: a first sidewall located between an upper surface of the pad 104 and the upper surface of the insulating layer 106, and a second sidewall higher than the upper surface of the insulating layer 106. is The first insulation structure 216 is at least in contact with a part of the second sidewall. The first insulation structure 216 can reduce the tipping or fall-off risk of the first metal bump 114.

As shown in FIG. 7 and FIG. 8, in an embodiment, when a difference ΔD (D3<D4) between dimensions D3 and D4 of two adjacent second metal bumps 116 meets a first preset condition, a dimension D5 of the second insulation structure 218 on the sidewall of the second metal bump 116 with the dimension D3 is increased, to eliminate a stress difference between the second metal bump 116 with the dimension D3 and the second metal bump 116 with the dimension D4 caused by the dimension difference. For example, when the second insulation structure 218 surrounds the second metal bump 116, the dimension D5 of the second insulation structure 218 on the sidewall of the second metal bump 116 with the dimension D3 is increased to increase the area of the second insulation structure 218 surrounding the second metal bump 116 with the dimension D3, thereby eliminating the stress difference caused by the area difference of two adjacent second metal bumps 116. The first preset condition refers to that the difference ΔD is greater than or equal to a preset value. For example, the preset value causes an area difference between two adjacent second metal bumps 116 to be greater than or equal to 4 times the area of the second metal bump 116 with the dimension D3. For example, when the dimensions D3 and D4 of the second metal bumps 116 are both less than 100 um and greater than 40 um, the first preset condition refers to that the difference ΔD is 15 um to 20 um, e.g., the difference ΔD is 15 um, 17 um, 19 um, 20 um or the like. When the dimensions D3 and D4 of the second metal bumps 116 are both less than or equal to 40 um, the first preset condition refers to that the difference ΔD is 5 um to 15 um, e.g., the difference ΔD is 5 um, 7 um, 9 um, 10 um, 13 um or the like. For example, a total area S1 of the second metal bump 116 with the dimension D3 and the second insulation structure 218 on the sidewall thereof is equal to a total area S2 of the second metal bump 116 with the dimension D4 and the second insulation structure 218 on the sidewall thereof. That is, two parts framed with dashed boxes in FIG. 8 have the same area. For example, ΔD is greater than or equal to 4 times of D3.

As shown in FIG. 7, in an embodiment, when the dimension D3 of the second metal is bump 116 is greater than or equal to a preset dimension, the second insulation structure 218 on the sidewall of the second metal bump 116 is spaced apart from the first insulation structure 216 on the sidewall of the neighboring first metal bump 114, and the second insulation structure 218 on the sidewall of the second metal bump 116 is spaced apart from the second insulation structure 218 on the sidewall of the neighboring second metal bump 116. When a distance D6 between the second metal bump 116 and the neighboring first metal bump 114 meets a second preset condition, and a distance D7 between the second metal bump 116 and the neighboring second metal bump 116 meets a third preset condition, the second insulation structure 218 on the sidewall of the second metal bump 116 is spaced apart from the first insulation structure 216 on the sidewall of the neighboring first metal bump 114, and the second insulation structure 218 on the sidewall of the second metal bump 116 is spaced apart from the second insulation structure 218 on the sidewall of the neighboring second metal bump 116. The preset dimension refers to a dimension of the second metal bump 116 in a case that the second metal bump 116 can be prevented from falling off or tipping by adding the second insulation structure 218 to the sidewall of the second metal bump 116. The second preset condition refers to that a difference between the distance D6 and the dimension of the second insulation structure 218 added to the sidewall of the second metal bump 116 is greater than the dimension of the first insulation structure 216 added to the sidewall of the neighboring first metal bump 114. The third preset condition refers to that a difference between the distance D7 and the dimension of the second insulation structure 218 added to the sidewall of the second metal bump 116 is greater than the dimension of the second insulation structure 218 added to the sidewall of the second metal bump 116. For example, the distance D6 is equal to the distance D7, and the distance D7 is greater than or equal to 20 um and less than or equal to 105 um, e.g., D7 is 30 um, 40 um, 45 um, 50 um, 70 um, 90 um, 100 um, etc.

In an embodiment, the insulation structure surrounds the second metal bump. As shown in FIG. 8, the second insulation structure 218 surrounds the second metal bump 116, which can further prevent the second metal bump 116 from falling off or tipping. The first insulation structure 216 surrounds the first metal bump 114, which can further prevent is the first metal bump 114 from falling off or tipping.

As shown in FIG. 9 and FIG. 10, in an embodiment, when the dimension D3 of the second metal bump 116 is less than the preset dimension, the distance D6 between the second metal bump 116 and the neighboring first metal bump 114 does not meet the second preset condition, and the distance D7 between the second metal bump 116 and the neighboring second metal bump 116 meets the third preset condition, the second insulation structure 218 on the sidewall of the second metal bump 116 is in contact with the first insulation structure 216 on the sidewall of the neighboring first metal bump 114, and the second insulation structure 218 on the sidewall of the second metal bump 116 is spaced apart from the second insulation structure 218 on the sidewall of the neighboring second metal bump 116. Such a configuration can prevent the first metal bump 114 and the second metal bump 116 from falling off or tipping.

As shown in FIG. 11 and FIG. 12, in an embodiment, when the dimension D3 of the second metal bump 116 is less than the preset dimension, the distance D6 between the second metal bump 116 and the neighboring first metal bump 114 meets the second preset condition, and the distance D7 between the second metal bump 116 and the neighboring second metal bump 116 does not meet the third preset condition, the second insulation structure 218 on the sidewall of the second metal bump 116 is spaced apart from the first insulation structure 216 on the sidewall of the first metal bump 114, and the second insulation structure 218 on the sidewall of the second metal bump 116 is in contact with the second insulation structure 218 on the sidewall of the second metal bump 116. Such a configuration can prevent the second metal bump 116 from falling off or tipping.

As shown in FIG. 13 and FIG. 14, in an embodiment, when the dimension D3 of the second metal bump 116 is less than the preset dimension, the distance D6 between the second metal bump 116 and the neighboring first metal bump 114 does not meet the second preset condition, and the distance D7 between the second metal bump 116 and the neighboring second metal bump 116 does not meet the third preset condition, the second insulation structure 218 on the sidewall of the second metal bump 116 is in contact with the first insulation structure 216 on the sidewall of the first metal bump 114, and the second insulation structure 218 on the sidewall of the second metal bump 116 is in contact is with the second insulation structure 218 on the sidewall of the second metal bump 116. Such a configuration can prevent the first metal bump 114 and the second metal bump 116 from falling off or tipping.

The technical characteristics of the above embodiments can be employed in arbitrary combinations. To provide a concise description, all possible combinations of all technical characteristics of the above embodiments may not be described; however, these combinations of technical characteristics should be construed as disclosed in the description as long as no contradiction occurs.

Only several embodiments of the present disclosure are described in detail above, but they should not therefore be construed as limiting the scope of the present disclosure. It should be noted that those of ordinary skill in the art can further make several variations and improvements without departing from the conception of the embodiments of the present disclosure. These variations and improvements all fall within the protection scope of the embodiments of the present disclosure. Therefore, the protection scope of the embodiments of the present disclosure should be subject to the protection scope defined by the claims.

1. A semiconductor structure, comprising:
a base comprising a pad;
an insulating layer, located on the base and provided with an opening that exposes the pad;
a first metal bump, located in the opening and being in contact with the pad;
a second metal bump, located on an upper surface of the insulating layer; and
an insulation structure, located on the upper surface of the insulating layer and being in contact with a sidewall of the second metal bump;
wherein an adhesion between the insulation structure and the insulating layer is greater than an adhesion between the second metal bump and the insulating layer.

2. The semiconductor structure according to claim 1, wherein the insulation structure comprises a first insulation structure and a second insulation structure, the first insulation structure is in contact with a sidewall of the first metal bump, and the second insulation structure is in contact with the sidewall of the second metal bump.

3. The semiconductor structure according to claim 2, wherein the second insulation structure comprises:
a first part in contact with the sidewall of the second metal bump; and
a second part in contact with the sidewall of the first part that is away from the second metal bump;
wherein the first part and the second part are each in a stepped shape.

4. The semiconductor structure according to claim 3, wherein a thickness of the first part is greater than a thickness of the second part.

5. The semiconductor structure according to claim 4, wherein a thickness of the first metal bump is greater than a thickness of the second metal bump.

6. The semiconductor structure according to claim 2, wherein a width of the first metal bump is less than a width of the opening, and the first insulation structure is further filled between a sidewall of the first metal bump and the opening.

7. The semiconductor structure according to claim 2, wherein the sidewall of the first metal bump comprises: a first sidewall located between an upper surface of the pad and the upper surface of the insulating layer, and a second sidewall higher than the upper surface of the insulating layer;
wherein the first insulation structure is at least in contact with a part of the second sidewall.

8. The semiconductor structure according to claim 1, wherein the insulation structure surrounds the second metal bump.

9. The semiconductor structure according to claim 1, wherein a material of the insulation structure is the same as a material of the insulating layer.

10. The semiconductor structure according to claim 2, wherein a thickness of the second insulation structure is inversely proportional to a dimension of the second metal bump.

11. A method of manufacturing a semiconductor structure, comprising:
providing a base comprising a pad;
forming an insulating layer on the base, wherein the insulating layer is provided with an opening that exposes the pad;
forming a first metal bump in the opening, wherein the first metal bump is in contact with the pad;
forming a second metal bump on an upper surface of the insulating layer; and
forming an insulation structure on at least the upper surface of the insulating layer, wherein the insulation structure is in contact with a sidewall of the second metal bump;
wherein an adhesion between the insulation structure and the insulating layer is greater than an adhesion between the second metal bump and the insulating layer.

12. The method of manufacturing according to claim 11, wherein the insulation structure comprises a first insulation structure and a second insulation structure;
wherein the first insulation structure is in contact with a sidewall of the first metal bump, and the second insulation structure is in contact with the sidewall of the second metal bump.

13. The method of manufacturing according to claim 12, wherein the second insulation structure comprises:
a first part in contact with the sidewall of the second metal bump; and
a second part in contact with the sidewall of the first part that is away from the second metal bump;
wherein the first part and the second part are each in a stepped shape.

14. The method of manufacturing according to claim 13, wherein a thickness of the first part is greater than a thickness of the second part.

15. The method of manufacturing according to claim 12, wherein a width of the first metal bump is less than a width of the opening, and the first insulation structure is further formed between a sidewall of the first metal bump and the opening.

16. The method of manufacturing according to claim 11, wherein a material of the insulation structure is the same as a material of the insulating layer.

17. The method of manufacturing according to claim 11, wherein the insulation structure surrounds the second metal bump.
